(19) United States
(12) Patent Application Publication
(10) Pub. No.: US 2023/0005883 A1
(43) Pub. Date: Jan. 5, 2023

(54) SEMICONDUCTOR PACKAGE

(71) Applicant: SAMSUNG ELECTRONICS CO., LTD., Suwon-si (KR)

(72) Inventors: Hyunkeun Kim, Seoul (KR); Yunrae Cho, Guri-si (KR); Seungduk Baek, Hwaseong-si (KR)

(73) Assignee: SAMSUNG ELECTRONICS CO., LTD., Suwon-si (KR)

(21) Appl. No.: 17/857,651

(22) Filed: Jul. 5, 2022

(30) Foreign Application Priority Data
Jul. 5, 2021 (KR) 10-2021-0088081

(51) Int. Cl. H01L 25/065; H01L 23/367; H01L 23/13; H01L 25/18; H01L 23/538

(52) U.S. Cl. CPC H01L 25/0655; H01L 23/367; H01L 23/13; H01L 25/18; H01L 23/5386; H01L 23/562

(57) ABSTRACT

A semiconductor package is provided that includes: a package substrate; an interposer mounted on the package substrate; a first semiconductor chip mounted on the interposer; a plurality of second semiconductor chips mounted on the interposer to surround at least a portion of the first semiconductor chip; a heat radiation member arranged on the first semiconductor chip and the plurality of second semiconductor chips; and a heat blocking member extending from a portion of the heat radiation member and arranged in at least one space among a first space between the first semiconductor chip and at least one of the plurality of second semiconductor chips and a second space between at least two of the plurality of second semiconductor chips.

### CROSS-REFERENCE TO THE RELATED APPLICATION

This application is based on and claims priority under 35 U.S.C. § 119 to Korean Patent Application No. 10-2021-0088081, filed on Jul. 5, 2021, in the Korean Intellectual Property Office, the disclosure of which is incorporated by reference herein in its entirety.

### BACKGROUND

Embodiments of the present disclosure relate to a semiconductor package.

The storage capacity of semiconductor chips is increased and, at the same time, semiconductor packages including semiconductor chips are demanded to be thin and light. Also, research is being conducted to include semiconductor chips of various functions in a semiconductor package and to quickly drive the semiconductor chips. In response to this trend, research is being actively conducted to rapidly release heat generated from semiconductor chips to the outside of a semiconductor package and to reduce thermal interference between the semiconductor chips.

### SUMMARY

Embodiments of the present disclosure provide a semiconductor package capable of reducing thermal interference between semiconductor chips.

Also, embodiments of the present disclosure provide a semiconductor package capable of rapidly releasing heat generated from semiconductor chips to the outside.

Also, embodiments of the present disclosure provide a semiconductor package with improved structural reliability and improved operational performance of semiconductor chips.

According to one or more embodiments, a semiconductor package is provided. The semiconductor package includes: a package substrate; an interposer mounted on the package substrate; a first semiconductor chip mounted on the interposer; a plurality of second semiconductor chips mounted on the interposer to surround at least a portion of the first semiconductor chip; a heat radiation member arranged on the first semiconductor chip and the plurality of second semiconductor chips; and a heat blocking member extending from a portion of the heat radiation member and arranged in at least one space among a first space between the first semiconductor chip and at least one of the plurality of second semiconductor chips and a second space between at least two of the plurality of second semiconductor chips.

According to one or more embodiments, a semiconductor package is provided. The semiconductor package includes: a package substrate; an interposer mounted on the package substrate; a first semiconductor chip mounted on the interposer; a plurality of semiconductor stack structures mounted on the interposer to surround at least a portion of the first semiconductor chip, and including a plurality of semiconductor chips stacked in a vertical direction; and a heat radiation member arranged on the first semiconductor chip and the plurality of semiconductor stack structures. The heat radiation member includes: a first heat radiation wall extending on the first semiconductor chip and the plurality of semiconductor stack structures in a horizontal direction; and at least one second heat radiation wall extending from a portion of the first heat radiation wall in the vertical direction and surrounding the first semiconductor chip and the plurality of semiconductor stack structures. The semiconductor package further includes a heat blocking member extending from a portion of the heat radiation member and arranged in at least one space among a first space between the first semiconductor chip and at least one of the plurality of semiconductor stack structures and a second space between at least two of the plurality of semiconductor stack structures.

According to one or more embodiments, a semiconductor package is provided. The semiconductor package includes a package substrate and an interposer mounted on the package substrate. The interposer includes: an interposer substrate; an interposer through electrode passing through at least a portion of the interposer substrate in a vertical direction; an interposer connection terminal connected to the interposer through electrode and arranged between the interposer substrate and the package substrate; and a redistribution structure arranged on the interposer substrate. The semiconductor package further includes a logic semiconductor chip arranged on the redistribution structure of the interposer; a plurality of semiconductor stack structures arranged on the redistribution structure of the interposer to surround at least a portion of the logic semiconductor chip, and including a plurality of memory semiconductor chips stacked in the vertical direction; a heat radiation member arranged on the logic semiconductor chip and the plurality of semiconductor stack structures; and a heat blocking member extending from at least a portion of the heat radiation member and arranged in at least one space among a first space between the logic semiconductor chip and at least one of the plurality of semiconductor stack structures and a second space between at least two of the plurality of semiconductor stack structures.

### BRIEF DESCRIPTION OF THE DRAWINGS

Embodiments of the present disclosure will be more clearly understood from the following detailed description taken in conjunction with the accompanying drawings in which:

FIG. 1 is a plan layout of a semiconductor package according to an example embodiment of the present disclosure;

FIG. 2 is a cross-sectional view of the semiconductor package taken along the line II-IF of FIG. 1;

FIG. 3 is a cross-sectional view of the semiconductor package taken along the line of FIG. 1;

FIG. 4 is a first enlarged view of a region A in FIG. 2;

FIG. 5 is a second enlarged view of the region A in FIG. 2;

FIG. 6 is a plan layout of a semiconductor package according to an example embodiment of the present disclosure;

FIG. 7 is an enlarged view of a region B in FIG. 6;

FIG. 8 is a plan layout of a semiconductor package according to an example embodiment of the present disclosure;

FIG. 9 is a plan layout of a semiconductor package according to an example embodiment of the present disclosure;

FIG. 10 is a plan layout of a semiconductor package according to an example embodiment of the present disclosure;

FIG. 11 is a cross-sectional view of a semiconductor package according to an example embodiment of the present disclosure;

FIG. 12 is a cross-sectional view of a semiconductor package according to an example embodiment of the present disclosure;

FIG. 13 is a plan layout of a semiconductor package according to an example embodiment of the present disclosure;

FIG. 14 is a cross-sectional view of the semiconductor package taken along the line XIV-XIV′ of FIG. 13;

FIG. 15 is a cross-sectional view of the semiconductor package taken along the line XV-XV′ of FIG. 13;

FIG. 16 is a plan layout of a semiconductor package according to an example embodiment of the present disclosure;

FIG. 17 is a plan layout of a semiconductor package according to an example embodiment of the present disclosure;

FIG. 18 is a flowchart of a method of manufacturing a semiconductor package, according to an example embodiment of the present disclosure;

FIG. 19 is a first diagram showing operations of a method of manufacturing a semiconductor package, according to an example embodiment of the present disclosure;

FIG. 20 is a second diagram showing operations of the method of manufacturing the semiconductor package, according to the example embodiment of the present disclosure;

FIG. 21 is a third diagram showing operations of the method of manufacturing the semiconductor package, according to the example embodiment of the present disclosure;

FIG. 22 is a fourth diagram showing operations of the method of manufacturing the semiconductor package, according to the example embodiment of the present disclosure.

### DETAILED DESCRIPTION OF THE EMBODIMENTS

Hereinafter, non-limiting example embodiments of the present disclosure will be described in detail with reference to the accompanying drawings.

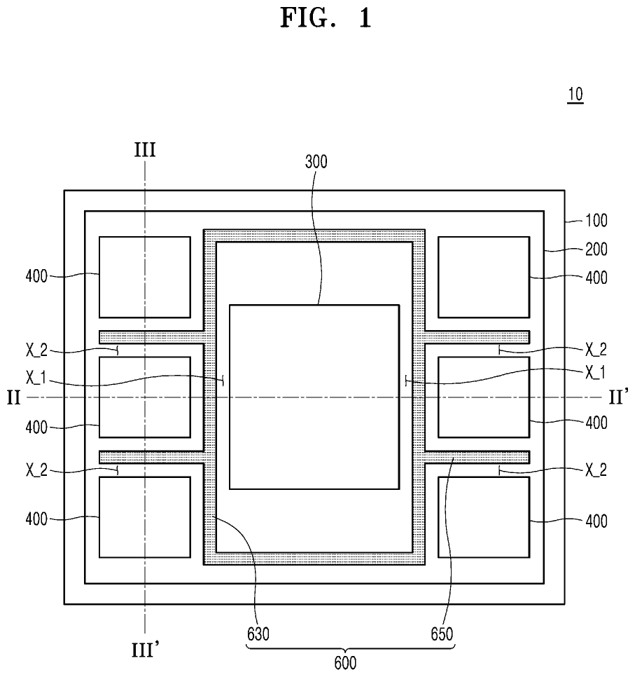

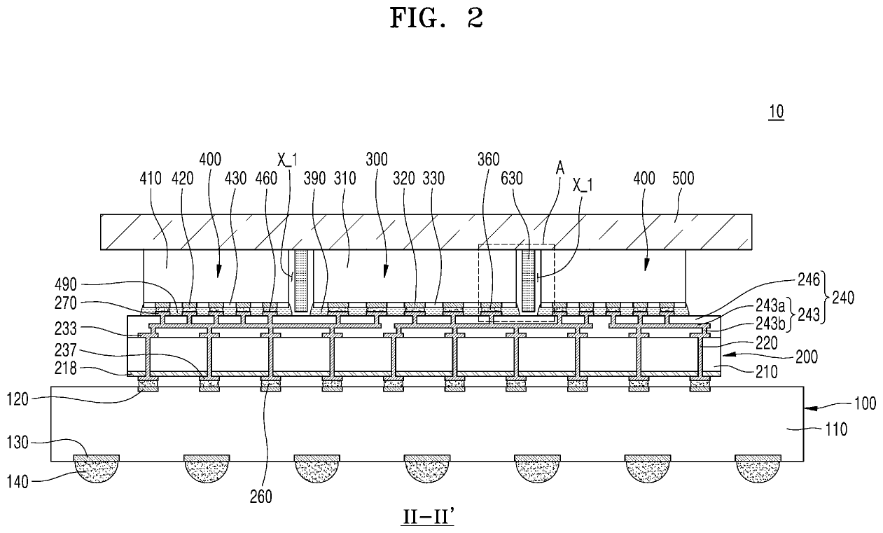

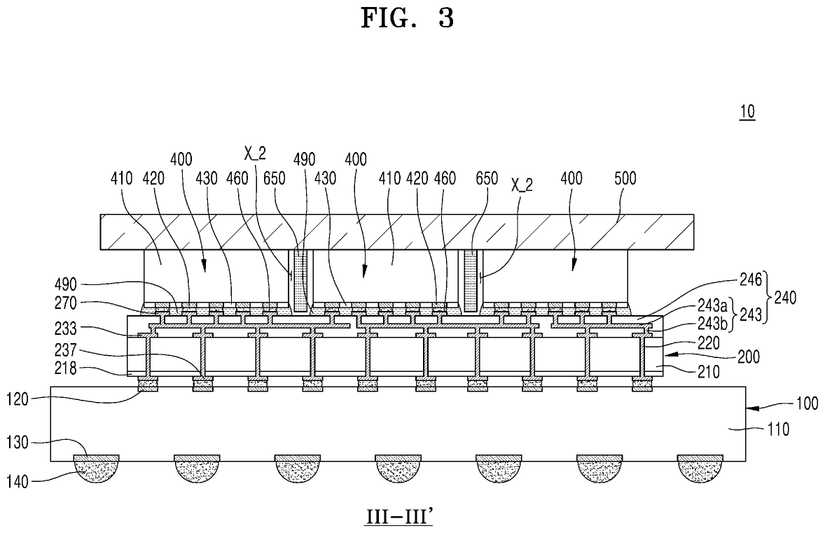

FIG. 1 is a plan layout of a semiconductor package 10 according to an example embodiment of the present disclosure. Also, FIG. 2 is a cross-sectional view of the semiconductor package 10 taken along the line II-IF of FIG. 1, and FIG. 3 is a cross-sectional view of the semiconductor package 10 taken along the line of FIG. 1.

Referring to FIGS. 1 to 3 together, the semiconductor package 10 according to an example embodiment of the present disclosure may include a package substrate 100, an interposer 200, a first semiconductor chip 300, a second semiconductor chip 400, a heat radiation member 500, a heat blocking member 600, and the like.

The package substrate 100 of the semiconductor package 10 may include a base board layer 110, an upper package substrate pad 120 arranged on an upper surface of the base board layer 110, a lower package substrate pad 130 arranged on a lower surface of the base board layer 110, and a package connection terminal 140 attached to the lower package substrate pad 130.

In an example embodiment, the package substrate 100 may be a printed circuit board (PCB). For example, the package substrate 100 may be a multi-layer PCB.

The base board layer 110 may include at least one material among phenol resin, epoxy resin, and polyimide. For example, the base board layer 110 may include at least one material among flame retardant 4 (FR4), tetrafunctional epoxy, polyphenylene ether, epoxy/polyphenylene oxide, bismaleimide triazine (BT), thermount, cyanate ester, polyimide, and a liquid crystal polymer.

In an example embodiment, the base board layer 110 may include, for example, polyester, polyester terephthalate, fluorinated ethylene propylene (FEP), resin-coated paper, liquid polyimide resin, polyethylene naphthalate (PEN) film, or the like.

The upper package substrate pad 120 may be a pad arranged on the upper surface of the base board layer 110 and in contact with an interposer connection terminal 260 of the interposer 200. Also, the lower package substrate pad 130 may be a pad arranged on the lower surface of the base board layer 110 and in contact with the package connection terminal 140.

In an example embodiment, the upper package substrate pad 120 and the lower package substrate pad 130 may include at least one material among copper (Cu), nickel (Ni), stainless steel, and beryllium copper.

Also, the package substrate 100 may include a substrate wiring pattern (not shown) extending within the base board layer 110 and configured to connect the upper package substrate pad 120 to the lower package substrate pad 130. The substrate wiring pattern may include a substrate wiring line pattern (not shown) extending in a horizontal direction within the base board layer 110, and a substrate wiring via pattern (not shown) extending in a vertical direction within the base board layer 110.

Hereinafter, the horizontal direction may be defined as a direction parallel to a direction in which an upper surface and a lower surface of the package substrate 100 extend, and the vertical direction may be defined as a direction perpendicular to the horizontal direction and perpendicular to the direction in which the upper surface and the lower surface of the package substrate 100 extend.

In an example embodiment, a material of the substrate wiring pattern may include at least one of electrolytically deposited (ED) copper, rolled-annealed (RA) copper foil, stainless steel foil, aluminum foil, ultra-thin copper foil, sputtered copper, copper alloys, nickel, stainless steel, and beryllium copper.

Also, the base board layer 110 may further include a solder resist layer (not shown) exposing a plurality of the upper package substrate pad 120 and a plurality of the lower package substrate pad 130 on the upper surface and the lower surface thereof, respectively. The solder resist layer may include at least one material among polyimide film, polyester film, flexible solder mask, photoimageable coverlay (PIC), and photo-imageable solder resist.

For example, the solder resist layer may be formed by thermally curing a thermosetting ink applied by a silk screen printing method or an inkjet method. Also, the solder resist layer may be formed by removing and then thermally curing a portion of photo-imageable solder resist applied by a screen method or a spray coating method through exposure and development. Also, the solder resist layer may be formed by laminating polyimide film or polyester film.

The package connection terminal 140 may be attached to one surface of the lower package substrate pad 130 to electrically connect the semiconductor package 10 to an external device. The package connection terminal 140 may be a solder ball including at least one material among copper (Cu), aluminum (Al), silver (Ag), tin, and gold (Au).

The interposer 200 of the semiconductor package 10 may be mounted on the package substrate 100. Also, the interposer 200 may be configured to electrically connect the package substrate 100 to the first semiconductor chip 300 and the second semiconductor chip 400 mounted on the interposer 200.

In an example embodiment, when the semiconductor package 10 is viewed from above, a horizontal cross-sectional area of the interposer 200 may be less than a horizontal cross-sectional area of the package substrate 100. Also, a horizontal length of the interposer 200 may be less than a horizontal length of the package substrate 100.

The interposer 200 may include an interposer substrate 210, an interposer through electrode 220, an interposer upper pad 233, an interposer lower pad 237, a redistribution structure 240, the interposer connection terminal 260, a chip connection pad 270, and the like.

The interposer substrate 210 of the interposer 200 may include a semiconductor material, glass, ceramic, plastic, or the like. For example, the interposer substrate 210 may include silicon. Example embodiments, however, are not limited thereto, and the interposer substrate 210 may include at least one material among an oxide, a nitride, and photo imageable dielectric (PID). For example, the interposer substrate 210 may include a silicon oxide, a silicon nitride, epoxy, or polyimide.

The interposer through electrode 220 of the interposer 200 may pass through at least a portion of the interposer substrate 210 in the vertical direction. Also, the interposer through electrode 220 may be provided in a multiple number. Also, a plurality of the interposer through electrode 220 may be configured to electrically connect a plurality of the interposer upper pad 233 to a plurality of the interposer lower pad 237, respectively.

In an example embodiment, each of the plurality of the interposer through electrode 220 may include a conductive plug penetrating the interposer substrate 210, and a conductive barrier layer surrounding the conductive plug. The conductive plug may have a columnar shape, and the conductive barrier layer may have a cylindrical shape surrounding a sidewall of the conductive plug. Also, a plurality of via insulating layers (not shown) may be between the plurality of the interposer through electrode 220 and the interposer substrate 210 to surround sidewalls of the plurality of the interposer through electrode 220.

Example embodiments, however, are not limited thereto, and an interposer redistribution pattern electrically connecting the interposer upper pad 233 to the interposer lower pad 237 may be arranged in the interposer substrate 210.

In an example embodiment, the interposer 200 may further include an interposer passivation layer 218 arranged on a lower surface of the interposer substrate 210 and surrounding a portion of side surfaces of the plurality of the interposer through electrode 220.

In an example embodiment, the interposer upper pad 233 and the interposer lower pad 237 may include at least one of copper (Cu), nickel (Ni), stainless steel, and beryllium copper.

Also, the interposer upper pad 233 may be connected to a redistribution pattern 243 of the redistribution structure 240, and the interposer lower pad 237 may be connected to the interposer connection terminal 260.

The interposer connection terminal 260 of the interposer 200 is between the upper package substrate pad 120 of the package substrate 100 and the interposer lower pad 237, and may be configured to electrically connect the interposer 200 to the package substrate 100. For example, the interposer connection terminal 260 may include at least one material among copper (Cu), aluminum (Al), silver (Ag), tin, and gold (Au).

The redistribution structure 240 of the interposer 200 may be arranged on the interposer substrate 210 to support a plurality of the first semiconductor chip 300 and the second semiconductor chip 400. Also, the redistribution structure 240 may be a structure configured to electrically connect the plurality of the first semiconductor chip 300 and the second semiconductor chip 400 to a plurality of the interposer through electrode 220.

In an example embodiment, the redistribution structure 240 may include a redistribution insulating layer 246 and the redistribution pattern 243 extending within the redistribution insulating layer 246. The redistribution insulating layer 246 is arranged on an upper surface of the interposer substrate 210, and may be a layer of an insulating material surrounding the redistribution pattern 243.

In an example embodiment, the redistribution insulating layer 246 may include an oxide or a nitride. For example, the redistribution insulating layer 246 may include a silicon oxide or a silicon nitride. Also, the redistribution insulating layer 246 may include an insulating material of a PID material on which a photolithography process may be performed. For example, the redistribution insulating layer 246 may include photosensitive polyimide (PSPI).

The redistribution pattern 243 may extend within the redistribution insulating layer 246, and may be configured to electrically connect the plurality of the first semiconductor chip 300 and the second semiconductor chip 400 to the plurality of the interposer through electrode 220. Also, the redistribution pattern 243 may include a redistribution line pattern 243a extending in the horizontal direction within the redistribution insulating layer 246 and a redistribution via pattern 243b extending in the vertical direction within the redistribution insulating layer 246.

In an example embodiment, the redistribution line pattern 243a may connect a plurality of the redistribution via pattern 243b to each other. Also, the redistribution via pattern 243b may electrically connect the interposer upper pad 233 to the redistribution line pattern 243a, and may electrically connect the chip connection pad 270 to the redistribution line pattern 243a.

In an example embodiment, a material of the redistribution pattern 243 may include copper (Cu). Example embodiments, however, are not limited thereto, and the material of the redistribution pattern 243 may be a metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), and ruthenium (Ru), or an alloy thereof.

The chip connection pad 270 may be a pad arranged on the redistribution structure 240 and electrically connected to the redistribution via pattern 243b. The chip connection pad 270 may electrically connect the plurality of the first semiconductor chip 300 and the second semiconductor chip 400 to the redistribution structure 240, and may be in contact with chip connection terminals (also respectively referred to as a first chip connection terminal 360 and a second chip connection terminal 460).

The first semiconductor chip 300 may be mounted on a central portion of the redistribution structure 240 of the interposer 200. In an example embodiment, when the semiconductor package 10 is viewed from above, a horizontal cross-sectional area of the first semiconductor chip 300 may be greater than a horizontal cross-sectional area of the second semiconductor chip 400. Also, a horizontal length of the first semiconductor chip 300 may be greater than a horizontal length of the second semiconductor chip 400.

In an example embodiment, the first semiconductor chip 300 may include a logic semiconductor chip. The logic semiconductor chip may include, for example, a logic semiconductor chip like a central processor unit (CPU), a microprocessor unit (MPU), a graphics processor unit (GPU), or an application processor (AP).

The first semiconductor chip 300 may include a first semiconductor substrate 310, a first chip pad 320, a first passivation layer 330, and the first chip connection terminal 360.

The first semiconductor substrate 310 may include silicon (Si). Also, the first semiconductor substrate 310 may include a semiconductor element such as germanium (Ge), or a compound semiconductor such as silicon carbide (SiC), gallium arsenide (GaAs), indium arsenide (InAs), and indium phosphide (InP).

In an example embodiment, the first semiconductor substrate 310 may include an active layer (not shown) in a portion adjacent to the interposer 200. The active layer may include a plurality of individual devices of various types. For example, the plurality of individual devices may include various microelectronic devices, for example, a complementary metal-oxide semiconductor (CMOS) transistor, a metal-oxide-semiconductor field effect transistor (MOSFET), a system large scale integration (LSI), an image sensor like a CMOS imaging sensor (CIS), a micro-electro-mechanical system (MEMS), an active device, a passive device, and the like.

The first chip pad 320 may be a pad arranged on one surface of the first semiconductor substrate 310 and electrically connected to the plurality of individual devices in the active layer. Also, the first passivation layer 330 may be a layer surrounding a side surface of the first chip pad 320.

In an example embodiment, a material of the first passivation layer 330 may include a silicon nitride (SiN). Example embodiments, however, are not limited thereto, and the material of the first passivation layer 330 may include one of a silicon oxynitride (SiON), a silicon oxide (SiO₂), a silicon carbonitride (SiOCN), a silicon carbonitride (SiCN), or a combination thereof.

The first chip connection terminal 360 is arranged between the first chip pad 320 of the first semiconductor chip 300 and the chip connection pad 270 of the interposer 200, and may be configured to connect the plurality of individual devices in the first semiconductor chip 300 to the interposer 200. For example, the first chip connection terminal 360 may be a solder ball of a metal material including at least one of tin (Sn), silver (Ag), copper (Cu), and aluminum (Al).

In an example embodiment, the first semiconductor chip 300 may be attached onto the interposer 200 via a flip-chip bonding process using the first chip connection terminal 360.

In an example embodiment, a first underfill layer 390 may be between the first semiconductor chip 300 and the interposer 200, and may surround the first chip connection terminal 360. Also, the first underfill layer 390 may be configured to fix the first semiconductor chip 300 on the interposer 200.

The second semiconductor chip 400 may be mounted on an edge portion of the redistribution structure 240 of the interposer 200. Also, the second semiconductor chip 400 may be provided in a multiple number. A plurality of the second semiconductor chip 400 may be arranged outside from a side surface of the first semiconductor chip 300 to surround at least a portion of the first semiconductor chip 300.

In an example embodiment, six of the second semiconductor chip 400 may be provided. When the semiconductor package 10 is viewed from above, four of the six of the second semiconductor chip 400 may be mounted on a corner portion of the interposer 200, and two of the six of the second semiconductor chip 400 may be respectively arranged between corners of the interposer 200.

Example embodiments, however, are not limited thereto, and the number of second semiconductor chip 400 may be four. When the semiconductor package 10 is viewed from above, four of the second semiconductor chip 400 may be mounted on a corner portion of the interposer 200.

The second semiconductor chip 400 may include a memory semiconductor chip. The memory semiconductor chip may include, for example, a volatile memory semiconductor chip like dynamic random access memory (DRAM) or static random access memory (SRAM) and may also include a non-volatile memory semiconductor chip like phase-change random access memory (PRAM), magneto-resistive random access memory (MRAM) ferroelectric random access memory (FeRAM), or resistive random access memory (RRAM).

The second semiconductor chip 400 may include a second semiconductor substrate 410, a second chip pad 420, a second passivation layer 430, and the second chip connection terminal 460. According to embodiments, the description of the second semiconductor chip 400 may be substantially a duplicate of descriptions of the first semiconductor chip 300, and thus, detailed description thereof is omitted.

In an example embodiment, a second underfill layer 490 may be between the second semiconductor chip 400 and the interposer 200, and may surround the second chip connection terminal 460. Also, the second underfill layer 490 may be configured to fix the second semiconductor chip 400 on the interposer 200.

The semiconductor package 10 may be a system in package (SIP) in which the plurality of the first semiconductor chip 300 and the second semiconductor chip 400 of different types are electrically connected to each other to operate as a single system.

In an example embodiment, vertical lengths of the first semiconductor chip 300 and the second semiconductor chip 400 may be substantially equal to each other. In other words, thicknesses of the first semiconductor chip 300 and the second semiconductor chip 400 may be substantially equal to each other, and an upper surface of the first semiconductor chip 300 and an upper surface of the second semiconductor chip 400 may be coplanar with each other.

In an example embodiment, the first underfill layer 390 may be arranged between the first semiconductor chip 300 and the redistribution structure 240 to surround the first chip connection terminal 360, and the second underfill layer 490 may be arranged between the second semiconductor chip 400 and the redistribution structure 240 to surround the second chip connection terminal 460.

The heat radiation member 500 of the semiconductor package 10 may be arranged on the first semiconductor chip 300 and the second semiconductor chip 400. Also, the heat radiation member 500 may be configured to release heat generated from the first semiconductor chip 300 and the second semiconductor chip 400 to the outside.

In an example embodiment, the heat radiation member 500 may include a heat sink. Example embodiments, however, are not limited thereto, and the heat radiation member 500 may include at least one of a heat spreader, a heat pipe, and liquid cooled cold plate.

In an example embodiment, the heat radiation member 500 may be in contact with the upper surface of the first semiconductor chip 300 and the upper surface of the second semiconductor chip 400. For example, a lower surface of the heat radiation member 500, the upper surface of the first semiconductor chip 300, and the upper surface of the second semiconductor chip 400 may be coplanar with one another.

In an example embodiment, when the semiconductor package 10 is viewed from above, a horizontal cross-sectional area of the heat radiation member 500 is greater than a horizontal cross-sectional area of the interposer 200, but may be less than a horizontal cross-sectional area of the package substrate 100. Also, a horizontal length of the heat radiation member 500 may be greater than a horizontal length of the interposer 200 and may be less than a horizontal length of the package substrate 100.

In an example embodiment, the heat radiation member 500 may include at least one material among a metal-based material, a ceramic-based material, a carbon-based material, and a polymer-based material. For example, the heat radiation member 500 may include a metal-based material such as aluminum (Al), magnesium (Mg), copper (Cu), nickel (Ni), silver (Ag), and the like.

Also, the heat radiation member 500 may include a ceramic-based material such as boron nitride (BN), aluminum nitride (AlN), aluminum oxide (Al₂O₃), silicon carbide (SiC), and beryllium oxide (BeO), and the like. However, a material of the heat radiation member 500 is not limited to those set forth above.

The heat blocking member 600 may extend from a portion of the heat radiation member 500 in the vertical direction, and may be arranged in at least one space among a first space X_1 between the first semiconductor chip 300 and the second semiconductor chip 400 and a second space X_2 between the plurality of the second semiconductor chip 400.

In other words, the heat blocking member 600 may be arranged between the first semiconductor chip 300 and the second semiconductor chip 400 to block thermal interference between the first semiconductor chip 300 and the second semiconductor chip 400. Also, the heat blocking member 600 may be arranged between the plurality of the second semiconductor chip 400 to block thermal interference between the plurality of the second semiconductor chip 400. In other words, the heat blocking member 600 may extend from a portion of the heat radiation member 500 in the vertical direction, and may be configured to block horizontal flow of heat generated from the first semiconductor chip 300 and the second semiconductor chip 400.

When the first semiconductor chip 300 is a logic semiconductor chip and the plurality of the second semiconductor chip 400 are memory chips, an amount of heat generated from the first semiconductor chip 300 may be generally greater than an amount of heat generated from the second semiconductor chip 400.

Accordingly, the heat generated from the first semiconductor chip 300 may move in a direction toward the second semiconductor chip 400, and an operating temperature of the second semiconductor chip 400 may be increased by the heat generated from the first semiconductor chip 300. As the operating temperature of the second semiconductor chip 400 increases, operational performance of the second semiconductor chip 400 may be deteriorated.

Also, heat generated from one second semiconductor chip 400 may move in a direction toward another neighboring second semiconductor chip 400. Accordingly, an operating temperature of the plurality of the second semiconductor chip 400 may increase, and operational performance of the plurality of the second semiconductor chip 400 may be deteriorated.

The heat blocking member 600 according to an example embodiment of the present disclosure may be arranged in at least one space among the first space X_1 between the first semiconductor chip 300 and the second semiconductor chip 400 and the second space X_2 between the plurality of the second semiconductor chip 400. Accordingly, the heat blocking member 600 may block thermal interference between the first semiconductor chip 300 and the second semiconductor chip 400 and thermal interference between the plurality of the second semiconductor chip 400.

In an example embodiment, a material of the heat blocking member 600 may be a material with a lower thermal conductivity than that of the material of the heat radiation member 500. The thermal conductivity may be defined as a measure of the ability of a material to transfer heat.

In an example embodiment, when the heat radiation member 500 includes a first metal material, a material of the heat blocking member 600 may include a second metal material with a lower thermal conductivity than that of the first metal material. For example, when the heat radiation member 500 includes copper (Cu), the material of the heat blocking member 600 may include stainless steel with a lower thermal conductivity than that of copper (Cu).

Because the heat blocking member 600 may include the second metal material with a lower thermal conductivity than that of the first metal material of the heat radiation member 500, the heat blocking member 600 may block thermal interference between the first semiconductor chip 300 and the second semiconductor chip 400 and thermal interference between the plurality of the second semiconductor chip 400.

At the same time, because the heat blocking member 600 may include a metal material with a relatively higher thermal conductivity than that of a non-metal material, heat transferred from the first semiconductor chip 300 and the second semiconductor chip 400 to the heat blocking member 600 may be rapidly transferred to the heat radiation member 500 by a thermal conduction phenomenon and may be released to the outside of the semiconductor package 10.

Also, when the heat radiation member 500 includes a metal material, a material of the heat blocking member 600 may include a non-metal material with a lower thermal conductivity than that of the heat radiation member 500. For example, when the heat radiation member 500 includes copper (Cu), the heat blocking member 600 may include an epoxy molding compound (EMC) with a lower thermal conductivity than that of copper (Cu).

Example embodiments, however, are not limited thereto, and a material of the heat radiation member 500 and a material of the heat blocking member 600 may be substantially identical to each other. For example, the material of the heat radiation member 500 and the material of the heat blocking member 600 may include copper (Cu).

Also, when the heat radiation member 500 and the heat blocking member 600 include the same material, the heat radiation member 500 and the heat blocking member 600 may be integrated. As the heat radiation member 500 and the heat blocking member 600 are integrated, a process of mounting the heat radiation member 500 and the heat blocking member 600 on the first semiconductor chip 300 and the second semiconductor chip 400 may be facilitated.

The heat blocking member 600 may include a first heat blocking wall 630 extending from a portion of the heat radiation member 500 in the vertical direction and arranged in the first space X_1 between the first semiconductor chip 300 and the second semiconductor chip 400.

In an example embodiment, when the semiconductor package 10 is viewed from above, the first heat blocking wall 630 may surround a side surface of the first semiconductor chip 300. For example, when the first semiconductor chip 300 includes four side surfaces, the first heat blocking wall 630 may surround the four side surfaces of the first semiconductor chip 300.

The heat blocking member 600 may include a second heat blocking wall 650 extending from a portion of the heat radiation member 500 in the vertical direction and arranged in the second space X_2 between the plurality of the second semiconductor chip 400.

In detail, the second heat blocking wall 650 may be provided in a multiple number. When the semiconductor package 10 is viewed from above, each of a plurality of the second heat blocking wall 650 may extend from the first heat blocking wall 630, and may be arranged in a respective one of the second space X_2 between the plurality of the second semiconductor chip 400.

In an example embodiment, the first heat blocking wall 630 and the second heat blocking wall 650 may include substantially the same material. Also, the first heat blocking wall 630 and the second heat blocking wall 650 may be integrated. Also, the first heat blocking wall 630 and the second heat blocking wall 650 may be fixed to a lower surface of the heat radiation member 500 and integrated with the heat radiation member 500.

In an example embodiment, a thickness of the first heat blocking wall 630 may be about 50 micrometers to 500 micrometers. For example, when the thickness of the first heat blocking wall 630 is less than about 50 micrometers, operational performance of the semiconductor package 10 may be deteriorated due to thermal interference between the first semiconductor chip 300 and the second semiconductor chip 400. Also, when the thickness of the first heat blocking wall 630 is greater than or equal to about 500 micrometers, operational performance of the semiconductor package 10 may be deteriorated as an electrical movement path between the first semiconductor chip 300 and the second semiconductor chip 400 increases. Also, a size of the semiconductor package 10 may increase.

Also, a thickness of the second heat blocking wall 650 may be about 50 micrometers to about 500 micrometers. For example, when a thickness of the second heat blocking wall 650 is less than about 50 micrometers, operational performance of the semiconductor package 10 may be deteriorated due to thermal interference between the plurality of the second semiconductor chip 400. Also, when a thickness of the second heat blocking wall 650 is greater than or equal to about 500 micrometers, a size of the semiconductor package 10 may increase.

In an example embodiment, a thickness of the first heat blocking wall 630 and a thickness of the second heat blocking wall 650 may be different from each other. For example, given that an amount of heat generated from the first semiconductor chip 300 is greater than an amount of heat generated from the second semiconductor chip 400, a thickness of the first heat blocking wall 630 may be greater than a thickness of the second heat blocking wall 650. Example embodiments, however, are not limited thereto, and a thickness of the first heat blocking wall 630 and a thickness of the second heat blocking wall 650 may be substantially equal to each other.

The semiconductor package 10 according to an example embodiment of the present disclosure may include the heat blocking member 600 arranged in at least one space among the first space X_1 between the first semiconductor chip 300 and the second semiconductor chip 400 and the second space X_2 between the plurality of the second semiconductor chip 400. Accordingly, thermal interference between the first semiconductor chip 300 and the second semiconductor chip 400 and thermal interference between the plurality of the second semiconductor chip 400 may be blocked by the heat blocking member 600, and operational performance of the first semiconductor chip 300 and the second semiconductor chip 400 may be improved.

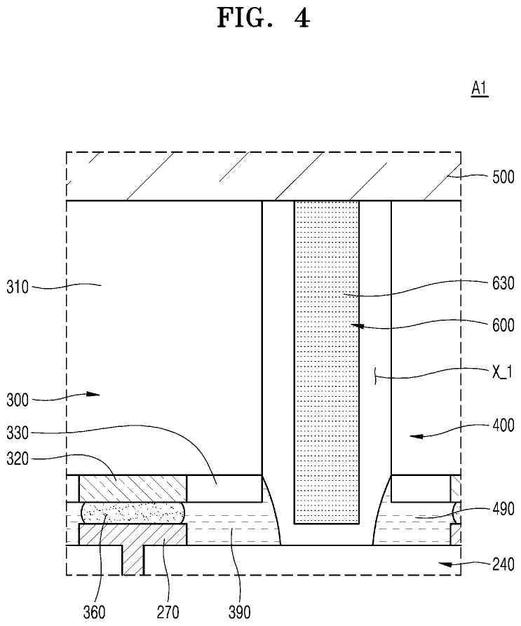

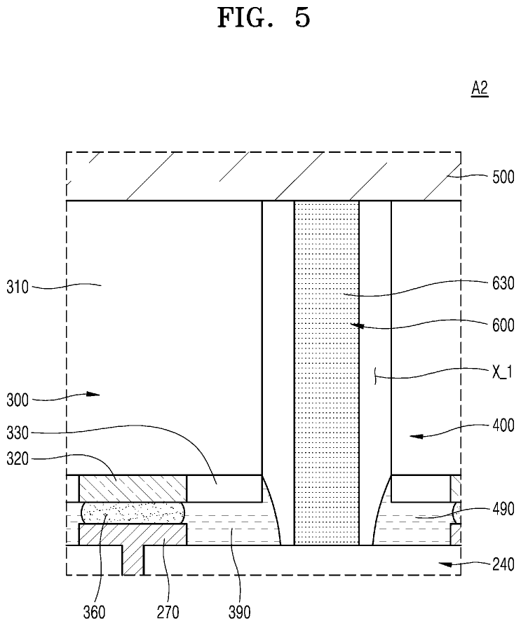

FIGS. 4 and 5 are enlarged views of a region A in FIG. 2.

Referring to FIG. 4, the heat blocking member 600 of the semiconductor package 10 may be spaced apart from the redistribution structure 240 of the interposer 200 in a vertical direction. In other words, a lower surface of the heat blocking member 600 may be at a higher level than an upper surface of the redistribution structure 240.

In an example embodiment, a level of the lower surface of the heat blocking member 600 may be between a level of lower surfaces of the first semiconductor chip 300 and the second semiconductor chip 400 and the upper surface of the redistribution structure 240. That is, surfaces toward the first semiconductor chip 300 and the second semiconductor chip 400 among surfaces of the heat blocking member 600 may overlap side surfaces of the first the first semiconductor chip 300 and the second semiconductor chip 400.

A level of the lower surface of the heat blocking member 600 may be between a level of the lower surfaces of the first semiconductor chip 300 and the second semiconductor chip 400 and a level of the upper surface of the redistribution structure 240, and thus, the heat blocking member 600 may block thermal interference between the first semiconductor chip 300 and the second semiconductor chip 400 and thermal interference between the plurality of the second semiconductor chip 400.

Also, the lower surface of the heat blocking member 600 may be at a higher level than the upper surface of the redistribution structure 240, and thus, in an operation of arranging the heat radiation member 500 to which the heat blocking member 600 is attached on the first semiconductor chip 300 and the second semiconductor chip 400, physical damage to the interposer 200 may be prevented by the heat blocking member 600.

Referring to FIG. 5, the heat blocking member 600 of the semiconductor package 10 may be in contact with the redistribution structure 240 of the interposer 200. In other words, the lower surface of the heat blocking member 600 may be coplanar with the upper surface of the redistribution structure 240.

A level of the lower surface of the heat blocking member 600 may be equal to a level of the upper surface of the redistribution structure 240, and thus, the heat blocking member 600 may block thermal interference between the first semiconductor chip 300 and the second semiconductor chip 400 and thermal interference between the plurality of the second semiconductor chip 400.

Also, a vertical length of the heat blocking member 600 may be substantially equal to a vertical distance between upper surfaces of the first semiconductor chip 300 and the second semiconductor chip 400 and the upper surface of the redistribution structure 240, and thus, in the operation of arranging the heat radiation member 500 to which the heat blocking member 600 is attached on the first semiconductor chip 300 and the second semiconductor chip 400, the lower surface of the heat blocking member 600 may function as a stopper.

In an example embodiment, a lower portion of the heat blocking member 600 may be round. In other words, the lower surface of the heat blocking member 600 may include a curved surface. When the lower portion of the heat blocking member 600 is round, in the operation of arranging the heat radiation member 500 to which the heat blocking member 600 is attached on the first semiconductor chip 300 and the second semiconductor chip 400, physical damage to the redistribution structure 240 may be prevented.

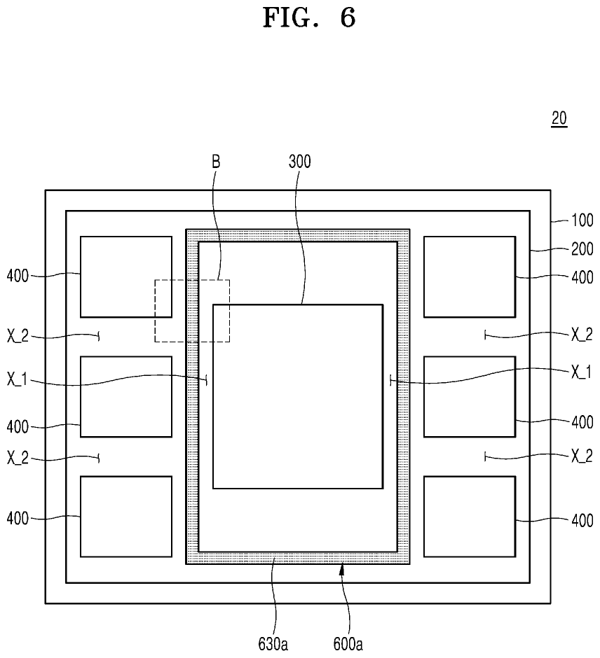

FIG. 6 is a plan layout of a semiconductor package 20 according to an example embodiment of the present disclosure.

Referring to FIG. 6, the semiconductor package 20 according to an example embodiment of the present disclosure may include a package substrate 100, an interposer 200, a first semiconductor chip 300, a second semiconductor chip 400, a heat radiation member 500, a heat blocking member 600a, and the like.

Hereinafter, duplicate descriptions between the semiconductor package 10 of FIGS. 1 to 3 and the semiconductor package 20 of FIG. 6 are omitted, and differences therebetween are mainly described.

The heat blocking member 600a of the semiconductor package 20 may include a first heat blocking wall 630a arranged in a first space X_1 between the first semiconductor chip 300 and the second semiconductor chip 400.

In an example embodiment, when the semiconductor package 20 is viewed from above, the first heat blocking wall 630a may surround a side surface of the first semiconductor chip 300. For example, when the first semiconductor chip 300 includes four side surfaces, the first heat blocking wall 630a may surround the four side surfaces of the first semiconductor chip 300.

For example, when the semiconductor package 20 is viewed from above, the first heat blocking wall 630a may be provided in a quadrangular shape surrounding the first semiconductor chip 300. Example embodiments, however, re not limited thereto, and the first heat blocking wall 630a may be provided in a circular or polygonal shape surrounding the first semiconductor chip 300.

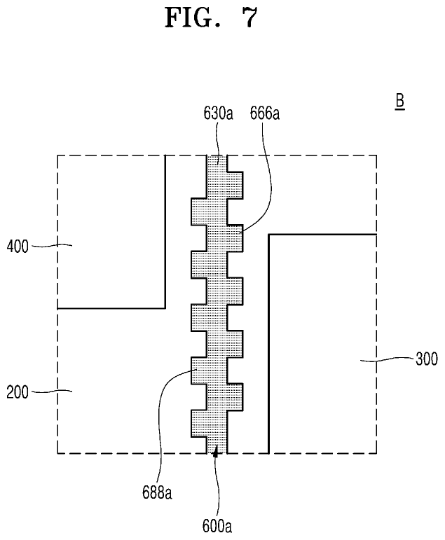

FIG. 7 is an enlarged view of a region B in FIG. 6.

Referring to FIG. 7, side surfaces of the heat blocking member 600a may have a concave-convex structure in which concavity and convexity are repeated. In detail, a surface toward the first semiconductor chip 300 among surfaces of the heat blocking member 600a may include a plurality of first protrusions 666a protruding in a direction toward the first semiconductor chip 300. Also, a surface toward the second semiconductor chip 400 among the surfaces of the heat blocking member 600a may include a plurality of second protrusions 688a protruding in a direction toward the second semiconductor chip 400.

The side surfaces of the heat blocking member 600a may have a concave-convex structure in which concavity and convexity are repeated, and thus, a surface area of the heat blocking member 600a may be increased. Also, due to an increase in the surface area of the heat blocking member 600a, the heat blocking member 600a may be rapidly received, from the first space X_1 between the first semiconductor chip 300 and the second semiconductor chip 400, heat generated from the first semiconductor chip 300 and the second semiconductor chip 400, and may transfer the received heat to the heat radiation member 500.

Also, the heat blocking member 600a may include the plurality of first protrusions 666a and the plurality of second protrusions 688a, and thus, a thickness of the heat blocking member 600a may relatively increase. The thickness of the heat blocking member 600a may relatively increase, and thus, the heat blocking member 600a may block thermal interference between the first semiconductor chip 300 and the second semiconductor chip 400.

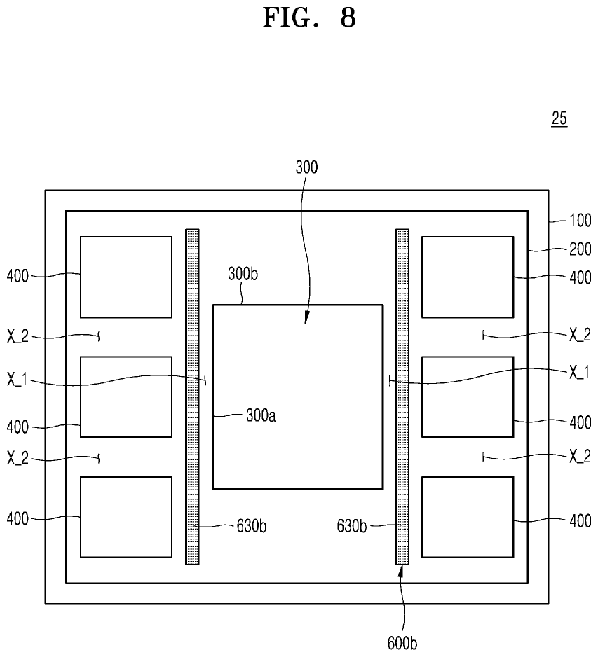

FIG. 8 is a plan layout of a semiconductor package 25 according to an example embodiment of the present disclosure.

Referring to FIG. 8, the semiconductor package 25 may include a package substrate 100, an interposer 200, a first semiconductor chip 300, a second semiconductor chip 400, a heat radiation member 500, a heat blocking member 600b, and the like.

The heat blocking member 600b may include a plurality of a first heat blocking wall 630b arranged outside a plurality of a first side surface 300a toward a plurality of the second semiconductor chip 400 among side surfaces of the first semiconductor chip 300. The first heat blocking wall 630b may be arranged outside the first side surface 300a of the first semiconductor chip 300, but may not be arranged outside a second side surface 300b vertically extending from the first side surface 300a among the side surfaces of the first semiconductor chip 300.

That is, the heat blocking member 600b surrounds the plurality of the first side surface 300a of the first semiconductor chip 300, but may not surround a plurality of the second side surface 300b vertically extending from the plurality of the first side surface 300a.

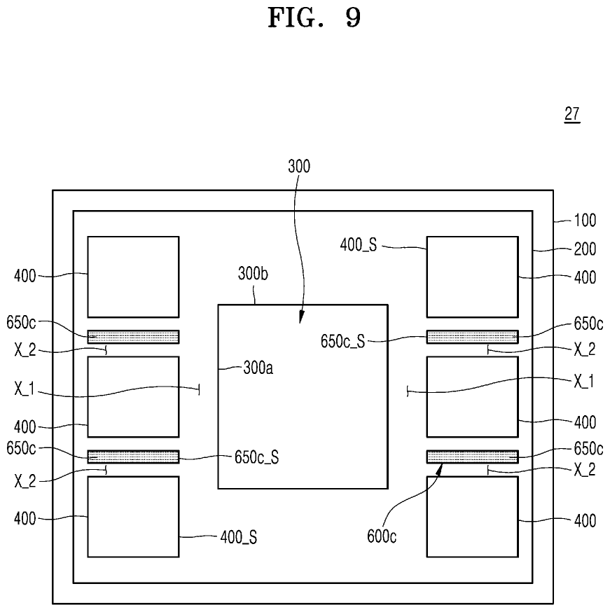

FIG. 9 is a plan layout of a semiconductor package 27 according to an example embodiment of the present disclosure.

Referring to FIG. 9, the semiconductor package 27 may include a package substrate 100, an interposer 200, a first semiconductor chip 300, a second semiconductor chip 400, a heat radiation member 500, a heat blocking member 600c, and the like.

The heat blocking member 600c may include a plurality of a second heat blocking wall 650c respectively arranged between two of a plurality of the second semiconductor chip 400. In detail, the second heat blocking wall 650c may be arranged outside the first semiconductor chip 300, and a direction in which the second heat blocking wall 650c extends may be perpendicular to a direction in which a first side surface 300a of the first semiconductor chip 300 extends, and may be parallel to a direction in which a second side surface 300b thereof extends.

In an example embodiment, a surface 650c_S toward the first semiconductor chip 300 among surfaces of the second heat blocking wall 650c may be coplanar with a surface 400_S toward the first semiconductor chip 300 among surfaces of the second semiconductor chip 400. That is, the surface 650c_S of the second heat blocking wall 650c and the surface 400_S of the second semiconductor chip 400 may be aligned with each other.

As the surface 650c_S of the second heat blocking wall 650c and the surface 400_S of the second semiconductor chip 400 are aligned with each other, a horizontal length of a first space X_1 between the first semiconductor chip 300 and the plurality of the second semiconductor chip 400 may decrease. Accordingly, an electrical movement path between the first semiconductor chip 300 and the plurality of the second semiconductor chip 400 may decrease, and operational performance of the first semiconductor chip 300 and the plurality of the second semiconductor chip 400 may be improved.

Also, as the plurality of the second heat blocking wall 650c of the semiconductor package 27 is arranged between the plurality of the second semiconductor chip 400, thermal interference between the plurality of the second semiconductor chip 400 may decrease. Accordingly, operational performance of the plurality of the second semiconductor chip 400 may be improved.

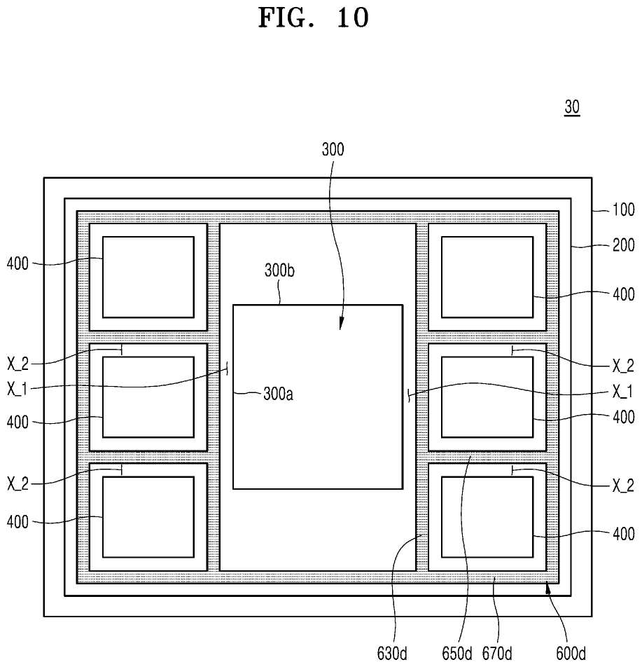

FIG. 10 is a plan layout of a semiconductor package 30 according to an example embodiment of the present disclosure.

Referring to FIG. 10, the semiconductor package 30 may include a package substrate 100, an interposer 200, a first semiconductor chip 300, a second semiconductor chip 400, a heat radiation member 500, a heat blocking member 600d, and the like.

In an example embodiment, the heat blocking member 600d may include a first heat blocking wall 630d arranged in a first space X_1 between the first semiconductor chip 300 and the second semiconductor chip 400 and surrounding the first semiconductor chip 300, a second heat blocking wall 650d extending from the first heat blocking wall 630d and arranged in a second space X_2 between a plurality of the second semiconductor chip 400, and a third heat blocking wall 670d arranged outside the plurality of the second semiconductor chip 400, connecting the first heat blocking wall 630d to the second heat blocking wall 650d, and surrounding the first semiconductor chip 300 and the plurality of the second semiconductor chip 400.

In an example embodiment, the heat blocking member 600d may surround the first semiconductor chip 300 and each of the plurality of the second semiconductor chip 400 by including the first heat blocking wall 630d, the second heat blocking wall 650d, and the third heat blocking wall 670d. The first semiconductor chip 300 and each of the plurality of the second semiconductor chip 400 may be surrounded by the heat blocking member 600d, and thus, thermal interference between the first semiconductor chip 300 and the second semiconductor chip 400 and thermal interference between the plurality of the second semiconductor chip 400 may be reduced.

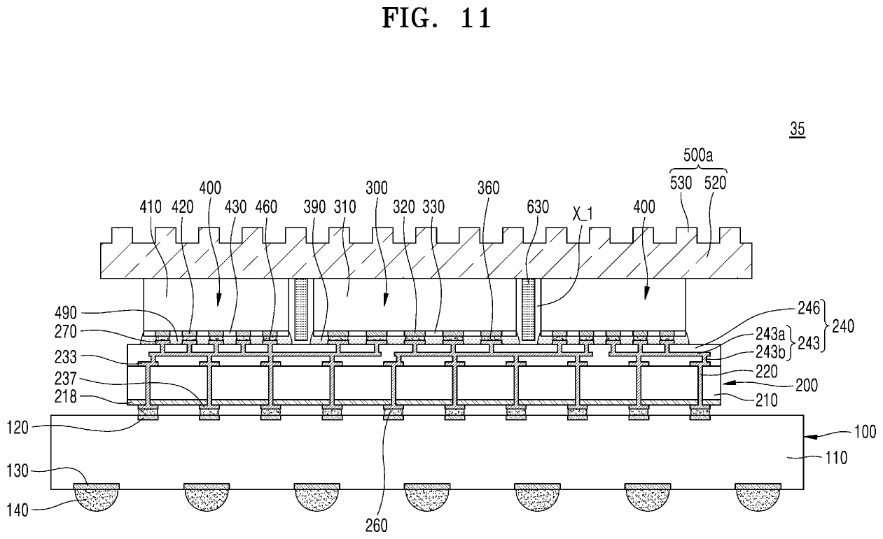

FIG. 11 is a cross-sectional view of a semiconductor package 35 according to an example embodiment of the present disclosure.

Referring to FIG. 11, the semiconductor package 35 may include a package substrate 100, an interposer 200, a first semiconductor chip 300, a second semiconductor chip 400, a heat radiation member 500a, a heat blocking member 600, and the like.

The heat radiation member 500a of the semiconductor package 35 may have a concave-convex structure in which concavity and convexity are repeated in a direction toward the outside of the semiconductor package 35. In an example embodiment, the heat radiation member 500a may include a base portion 520 and a plurality of protrusions 530 protruding from a surface of the base portion 520. The plurality of protrusions 530 may be repeatedly arranged to be spaced apart from each other by a certain distance. Accordingly, the heat radiation member 500a may have a concave-convex structure in which concavity and convexity are repeated.

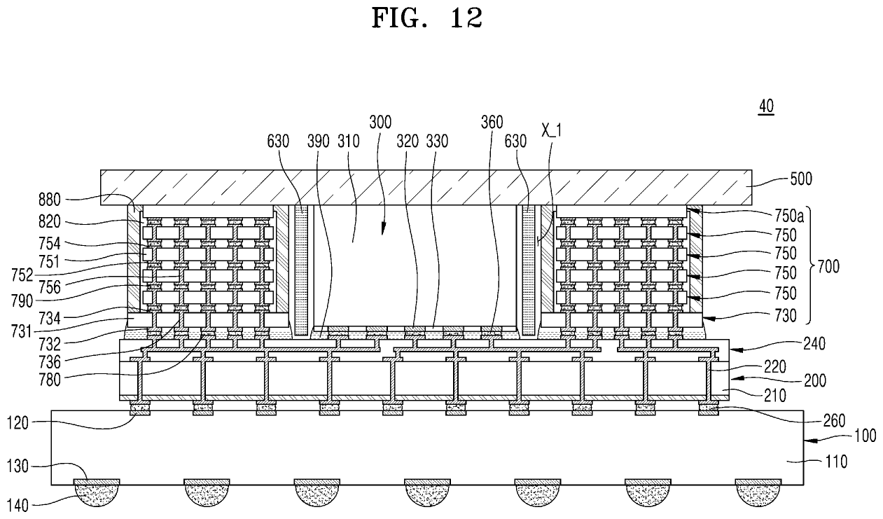

FIG. 12 is a cross-sectional view of a semiconductor package 40 according to an example embodiment of the present disclosure.

The semiconductor package 40 according to an example embodiment of the present disclosure may include a package substrate 100, an interposer 200, a first semiconductor chip 300, a semiconductor stack structure 700, a heat radiation member 500, a heat blocking member 600, and the like.

Hereinafter, duplicate descriptions between the semiconductor package 10 of FIGS. 1 to 3 and the semiconductor package 40 of FIG. 12 are omitted, and differences therebetween are mainly described.

The semiconductor stack structure 700 may be mounted on an edge portion of a redistribution structure 240 of the interposer 200. Also, the semiconductor stack structure 700 may be provided in a multiple number. A plurality of the semiconductor stack structure 700 may be arranged outside from a side surface of the first semiconductor chip 300 to surround at least a portion of the first semiconductor chip 300.

In an example embodiment, six of the semiconductor stack structure 700 may be provided. When the semiconductor package 40 is viewed from above, four of the six of the semiconductor stack structure 700 may be mounted on a corner portion of the interposer 200, and two of the six of the semiconductor stack structure 700 may be respectively arranged between corners of the interposer 200.

Example embodiments, however, are not limited thereto, and the number of semiconductor stack structure 700 may be four. When the semiconductor package 40 is viewed from above, four of the semiconductor stack structure 700 may be mounted on corner portions of the interposer 200, respectively.

The semiconductor stack structure 700 may include a second semiconductor chip 730 and a plurality of a third semiconductor chip 750 mounted on the second semiconductor chip 730. Although it is shown that the semiconductor stack structure 700 includes one second semiconductor chip 730 and three of the semiconductor chip 750, embodiments of the present disclosure are not limited thereto.

In an example embodiment, the semiconductor stack structure 700 may be a memory semiconductor stack structure. For example, the semiconductor stack structure 700 may be dynamic random access memory (DRAM), static random access memory (SRAM), flash memory, electrically erasable and programmable read-only memory (EEPROM), phase-change random access memory (PRAM), magnetic random access memory (MRAM), or resistive random access memory (RRAM).

In an example embodiment, the second semiconductor chip 730 may not include a memory cell, and a third semiconductor chip 750 may include a memory cell. For example, the second semiconductor chip 730 may be a test logic circuit such as a serial-parallel conversion circuit, a design for test (DFT), a joint test action group (JTAG), and a memory built-in self-test (MBIST), or a buffer chip including a signal interface circuit such as a PHY.

Also, the third semiconductor chip 750 may be a memory semiconductor chip. For example, when the second semiconductor chip 730 is a buffer chip for controlling of HBM DRAM, the third semiconductor chip 750 may be a second semiconductor chip including a cell of HBM DRAM controlled by the second semiconductor chip 730.

In an example embodiment, the second semiconductor chip 730 may include a second semiconductor substrate 731, a lower connection pad 732, an upper connection pad 734, and a plurality of through electrodes 736. Also, the third semiconductor chip 750 may include a third semiconductor substrate 751, a lower connection pad 752, an upper connection pad 754, and a plurality of through electrodes 756.

An active layer of the second semiconductor substrate 731 may include a plurality of individual devices. Also, the lower connection pad 732 may be arranged on a lower surface of the second semiconductor substrate 731 adjacent to the active layer, and the upper connection pad 734 may be arranged on an upper surface of the second semiconductor substrate 731. Also, the plurality of through electrodes 736 may electrically connect the lower connection pad 732 to the upper connection pad 734 by passing through at least a portion of the second semiconductor substrate 731 in a vertical direction.

Also, an active layer of the third semiconductor substrate 751 may include a plurality of individual devices. Also, the lower connection pad 752 may be arranged on a lower surface of the third semiconductor substrate 751 adjacent to the active layer, and the upper connection pad 754 may be arranged on an upper surface of the third semiconductor substrate 751. Also, the plurality of through electrodes 756 may electrically connect the lower connection pad 752 to the upper connection pad 754 by passing through at least a portion of the third semiconductor substrate 751 in a vertical direction. The plurality of through electrodes 756 of the third semiconductor chip 750 may be electrically connected to the plurality of through electrodes 736 of the second semiconductor chip 730.

A plurality of a second chip connection terminal 780 may be attached onto a plurality of the lower connection pad 732 of the second semiconductor chip 730, and a plurality of third chip connection terminals 790 may be attached onto a plurality of the lower connection pad 752 of the third semiconductor chip 750.

The plurality of the second chip connection terminal 780 may be arranged between the second semiconductor chip 730 and the redistribution structure 240 of the interposer 200 to electrically connect the semiconductor stack structure 700 to the interposer 200.

The third chip connection terminals 790 may be arranged between the upper connection pad 734 of the second semiconductor chip 730 and the lower connection pad 752 of the third semiconductor chip 750 to electrically connect the second semiconductor chip 730 to the third semiconductor chip 750. Also, the third chip connection terminals 790 may be arranged between a lower connection pad 752 and an upper connection pad 754 of each of the plurality of the third semiconductor chip 750 to electrically connect the plurality of the third semiconductor chip 750 to each other.

In an example embodiment, a horizontal length of the second semiconductor chip 730 may be greater than a horizontal length of the third semiconductor chip 750. Also, a horizontal cross-sectional area of the second semiconductor chip 730 may be greater than a horizontal cross-sectional area of the third semiconductor chip 750.

In an example embodiment, a third semiconductor chip 750a arranged farthest from the second semiconductor chip 730 in a vertical direction among the plurality of the third semiconductor chip 750 may not include the upper connection pad 754 and the through electrodes 756.

In an example embodiment, an insulating adhesive layer 820 may be arranged between the second semiconductor chip 730 and the third semiconductor chip 750 and between the plurality of the third semiconductor chip 750. Also, the insulating adhesive layer 820 may surround a side portion of the third chip connection terminals 790.

In an example embodiment, the insulating adhesive layer 820 may include a non-conductive film, (NCF), a non-conductive paste (NCP), an insulating polymer, an epoxy resin, or the like.

Also, the semiconductor stack structure 700 is arranged on the second semiconductor chip 730, and may further include a molding layer 880 surrounding the plurality of the third semiconductor chip 750. For example, the molding layer 880 may include an EMC.

In an example embodiment, the molding layer 880 may not cover an upper surface of the third semiconductor chip 750a at an uppermost end. In other words, an upper surface of the molding layer 880 may be coplanar with the upper surface of the third semiconductor chip 750a. Example embodiments, however, are not limited thereto, and the molding layer 880 may cover the upper surface of the third semiconductor chip 750a.

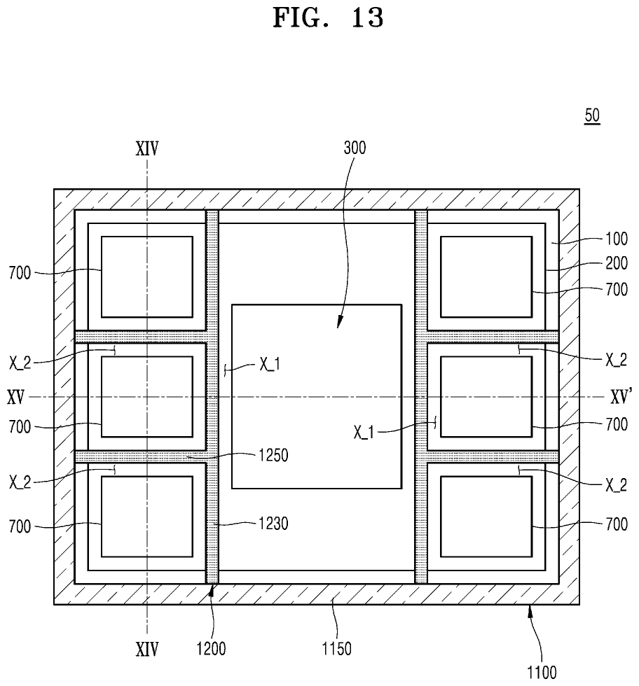

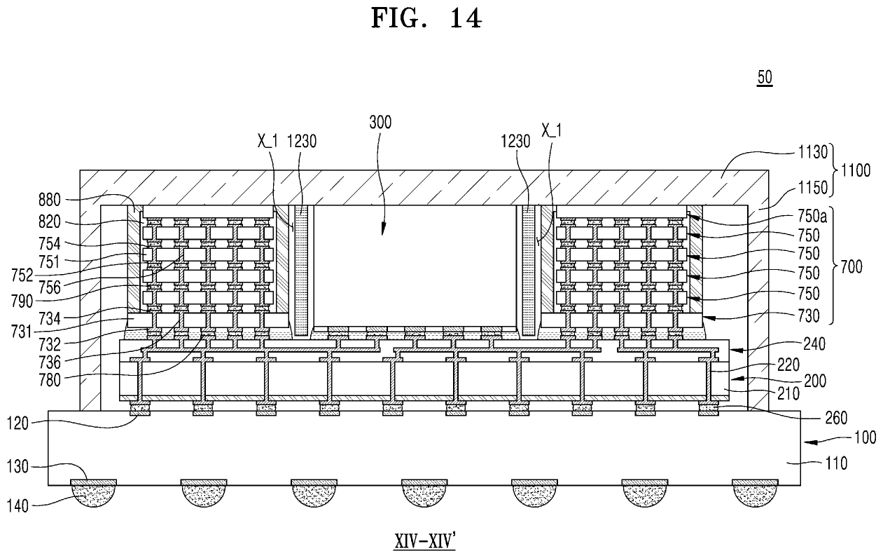

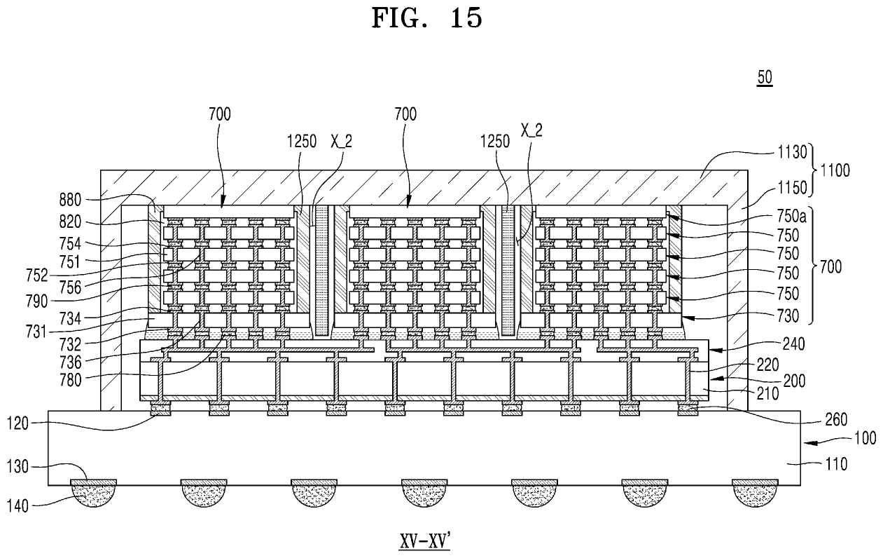

FIG. 13 is a plan layout of a semiconductor package 50 according to an example embodiment of the present disclosure. Also, FIG. 14 is a cross-sectional view of the semiconductor package 50 taken along the line XIV-XIV′ of FIG. 13, and FIG. 15 is a cross-sectional view of the semiconductor package 50 taken along the line XV-XV′ of FIG. 13.

Referring to FIGS. 13 to 15 together, the semiconductor package 50 according to an example embodiment of the present disclosure may include a package substrate 100, an interposer 200, a first semiconductor chip 300, a semiconductor stack structure 700, a heat radiation member 1100, a heat blocking member 1200, and the like.

Hereinafter, duplicate descriptions between the semiconductor package 40 of FIG. 12 and the semiconductor package 50 of FIGS. 13 to 15 are omitted, and differences therebetween are mainly described.

In an example embodiment, the heat radiation member 1100 may be supported by a portion of an upper surface of the package substrate 100. Also, the heat radiation member 1100 may be mounted on the package substrate 100 to surround the interposer 200, the first semiconductor chip 300, and the semiconductor stack structure 700.

In an example embodiment, the heat radiation member 1100 may include a first heat radiation wall 1130 horizontally extending to be arranged on upper portions of the first semiconductor chip 300 and the semiconductor stack structure 700, and a second heat radiation wall 1150 vertically extending from the first heat radiation wall 1130 and surrounding the first semiconductor chip 300 and the semiconductor stack structure 700.

In an example embodiment, the first heat radiation wall 1130 and the second heat radiation wall 1150 may include substantially the same material and may be integrated. Also, when the heat radiation member 1100 is viewed from above, the second heat radiation wall 1150 may have a quadrangular shape surrounding the first semiconductor chip 300 and the semiconductor stack structure 700.

In an example embodiment, the heat blocking member 1200 may include a first heat blocking wall 1230 arranged between the first semiconductor chip 300 and the semiconductor stack structure 700, and a second heat blocking wall 1250 arranged between a plurality of the semiconductor stack structure 700. Also, a material of the heat blocking member 1200 may be a material with a lower thermal conductivity than that of a material of the heat radiation member 1100.

In an example embodiment, the first heat blocking wall 1230 may extend between a plurality of the second heat radiation wall 1150 facing each other, and may be arranged in a first space X_1 between the first semiconductor chip 300 and the semiconductor stack structure 700. Also, when the semiconductor package 50 is viewed from above, the first heat blocking wall 1230 may surround a side surface of the first semiconductor chip 300.

Also, the first heat blocking wall 1230 may be integrated with the first heat radiation wall 1130 and the second heat radiation wall 1150.

In an example embodiment, the second heat blocking wall 1250 may extend from a portion of the second heat radiation wall 1150 and be connected to the first heat blocking wall 1230, and may be arranged in a second space X_2 between the plurality of the semiconductor stack structure 700. Also, when the semiconductor package 50 is viewed from above, the second heat blocking wall 1250 may surround a side surface of the semiconductor stack structure 700 together with the first heat blocking wall 1230.

According to embodiments, the heat radiation member 1100 and the heat blocking member 1200 may be the same or similar to those described with reference to FIGS. 1 to 12, and thus further detailed description thereof is omitted.

The semiconductor package 50 according to an example embodiment of the present disclosure may include the heat radiation member 1100 surrounding at least a portion of a side surface of the first semiconductor chip 300 and a side surface of the semiconductor stack structure 700. Accordingly, heat generated from the first semiconductor chip 300 and the semiconductor stack structure 700 may be rapidly released to the outside of the semiconductor package 50 through the heat radiation member 1100.

Also, the semiconductor package 50 according to an example embodiment of the present disclosure may include the heat blocking member 1200 arranged in the first space X_1 between the first semiconductor chip 300 and the semiconductor stack structure 700 or the second space X_2 between the plurality of the semiconductor stack structure 700. Accordingly, the semiconductor package 50 may reduce thermal interference between the first semiconductor chip 300 and the semiconductor stack structure 700 and thermal interference between the plurality of the semiconductor stack structure 700.

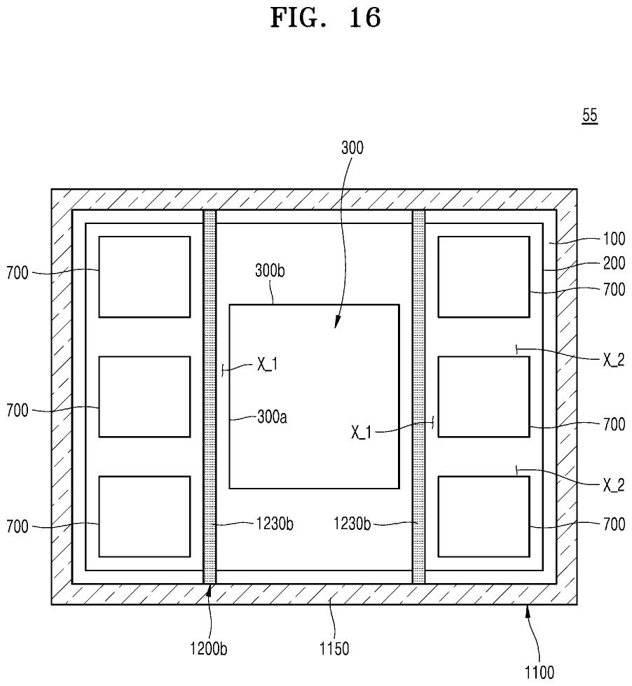

FIG. 16 is a plan layout of a semiconductor package 55 according to an example embodiment of the present disclosure.

Referring to FIG. 16, the semiconductor package 55 may include a package substrate 100, an interposer 200, a first semiconductor chip 300, a semiconductor stack structure 700, a heat radiation member 1100, a heat blocking member 1200b, and the like.

The heat blocking member 1200b may include a plurality of a first heat blocking wall 1230b arranged outside a plurality of a first side surface 300a, respectively, toward a plurality of the semiconductor stack structure 700 among side surfaces of the first semiconductor chip 300. That is, the first heat blocking wall 1230b may be arranged in a first space X_1 between the first semiconductor chip 300 and the semiconductor stack structure 700.

The first heat blocking wall 1230b may be arranged outside the first side surface 300a of the first semiconductor chip 300, but may not be arranged outside a second side surface 300b vertically extending from the first side surface 300a among the side surfaces of the first semiconductor chip 300.

That is, the heat blocking member 1200b surrounds the first side surface 300a of the first semiconductor chip 300, but may not surround the second side surface 300b vertically extending from the first side surface 300a. Also, the heat blocking member 1200b may be arranged between a plurality of the second heat radiation wall 1150 facing each other.

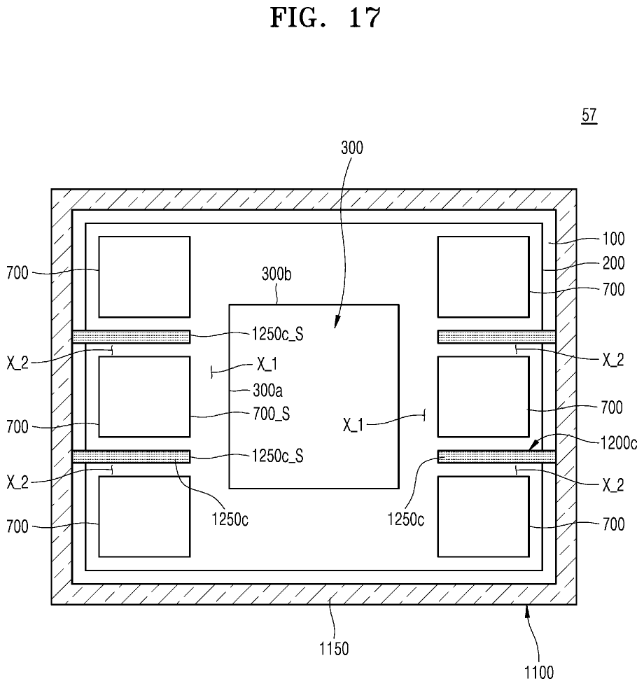

FIG. 17 is a plan layout of a semiconductor package 57 according to an example embodiment of the present disclosure.

Referring to FIG. 17, the semiconductor package 57 may include a package substrate 100, an interposer 200, a first semiconductor chip 300, a semiconductor stack structure 700, a heat radiation member 1100, a heat blocking member 1200c, and the like.

The heat blocking member 1200c may include a plurality of a second heat blocking wall 1250c arranged between a plurality of the semiconductor stack structure 700. In detail, the second heat blocking wall 1250c may be arranged outside the first semiconductor chip 300, and a direction in which the second heat blocking wall 1250c extends may be perpendicular to a direction in which a first side surface 300a of the first semiconductor chip 300 extends, and may be parallel to a direction in which a second side surface 300b is extends.

In an example embodiment, a surface 650c_S toward the first semiconductor chip 300 among surfaces of the second heat blocking wall 1250c may be coplanar with a surface 700_S toward the first semiconductor chip 300 among surfaces of the semiconductor stack structure 700. That is, a surface 1250c_S of the second heat blocking wall 1250c and the surface 700_S of the semiconductor stack structure 700 may be aligned with each other.

As the surface 1250c_S of the second heat blocking wall 1250c and the surface 700_S of the semiconductor stack structure 700 are aligned with each other, a horizontal length of a first space X_1 between the first semiconductor chip 300 and the semiconductor stack structure 700 may decrease. Accordingly, an electrical movement path between the first semiconductor chip 300 and the plurality of the semiconductor stack structure 700 may decrease, and operational performance of the first semiconductor chip 300 and the plurality of the semiconductor stack structure 700 may be improved.

Also, as the second heat blocking wall 1250c of the semiconductor package 57 is arranged between the plurality of the semiconductor stack structure 700, thermal interference between the plurality of the semiconductor stack structure 700 may decrease. Accordingly, operational performance of the plurality of the semiconductor stack structure 700 may be improved.

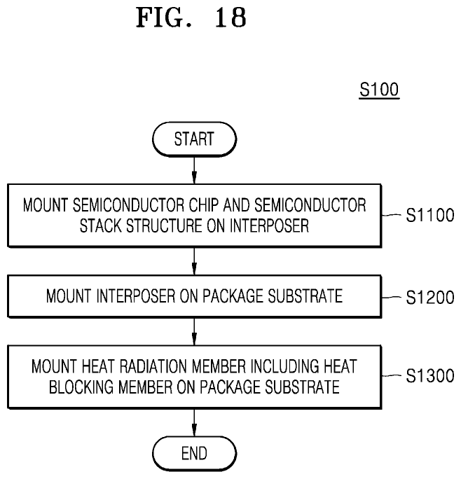

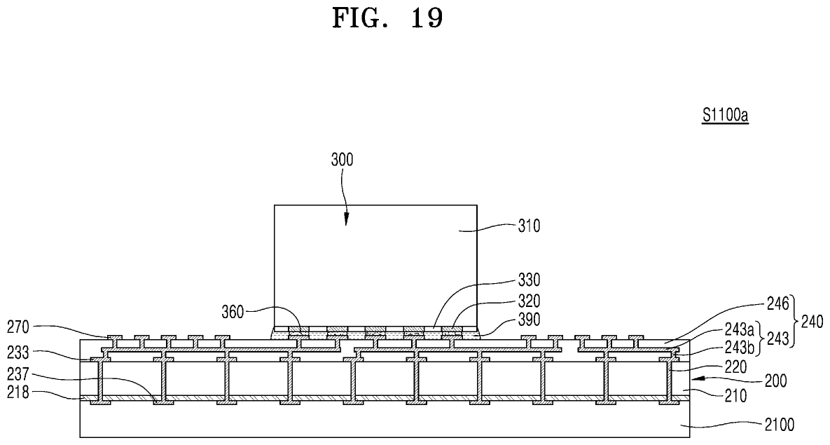

FIG. 18 is a flowchart of a method S100 of manufacturing the semiconductor package 50, according to an example embodiment of the present disclosure. Also, FIGS. 19 to 22 are diagrams showing operations of the method S100 of manufacturing the semiconductor package 50, according to an example embodiment of the present disclosure. The method S100 of manufacturing the semiconductor package 50 according to an example embodiment of the present disclosure may be a method of manufacturing the semiconductor package 50 described with reference to FIGS. 13 to 15.

The method S100 of manufacturing the semiconductor package 50 according to an example embodiment of the present disclosure may include mounting the first semiconductor chip 300 and the semiconductor stack structure 700 on the interposer 200 (operation S1100), mounting the interposer 200 on the package substrate 100 (operation S1200), and mounting the heat radiation member 1100 including the heat blocking member 1200 on the package substrate 100 (operation S1300).

Referring to FIGS. 18-20, the method S100 of manufacturing the semiconductor package 50 according to an example embodiment of the present disclosure may include mounting the first semiconductor chip 300 and the semiconductor stack structure 700 on the interposer 200 (operation S1100).

In an example embodiment, prior to performing operation S1100, a carrier substrate 2100 may be attached to a lower portion of the interposer 200. For example, the carrier substrate 2100 may be a substrate including any material having stability in a semiconductor process such as a baking process, an etching process, and the like.

In an example embodiment, when the carrier substrate 2100 is to be separated and removed by laser ablation, the carrier substrate 2100 may be a translucent substrate. Optionally, when the carrier substrate 2100 is to be separated and removed by heating, the carrier substrate 2100 may be a heat-resistant substrate.

In an example embodiment, the carrier substrate 2100 may be a glass substrate. Alternatively, in another example embodiment, the carrier substrate 2100 may include a heat-resistant organic polymer material such as polyimide (PI), polyetheretherketone (PEEK), polyethersulfone (PES), and polyphenylene sulfide (PPS), but is not limited thereto.

A release film (not shown) may be attached to one surface of the carrier substrate 2100. For example, the release film may be a laser reactive layer that is gasified in response to a subsequent laser irradiation to thereby allow the carrier substrate 2100 to be separated. The release film may include a carbon-based material layer. For example, the release film may include an amorphous carbon layer (ACL).

Operation S1100 may include mounting the first semiconductor chip 300 on the interposer 200 (operation S1100a). In an example embodiment, the first semiconductor chip 300 may be mounted on the interposer 200 through a flip-chip bonding process.

In an example embodiment, in operation S1100a, the first chip connection terminal 360 attached to the first chip pad 320 of the first semiconductor chip 300 may be in contact with the chip connection pad 270 of the interposer 200. Accordingly, in operation S1100, the first semiconductor chip 300 may be electrically connected to the interposer 200.

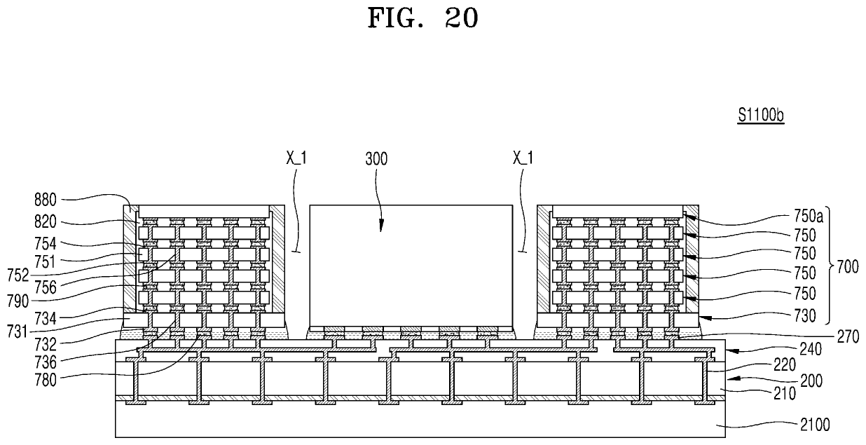

Referring to FIGS. 18 and 20, operation S1100 may include mounting the semiconductor stack structure 700 on the interposer 200 (operation S1100b). In an example embodiment, the semiconductor stack structure 700 may be mounted on the interposer 200 to surround a side portion of the first semiconductor chip 300. Also, the semiconductor stack structure 700 may be mounted on the interposer 200 through a flip-chip bonding process.

In an example embodiment, in operation S1100b, a second chip connection terminal 780 of the semiconductor stack structure 700 may be in contact with the chip connection pad 270 of the interposer 200. Accordingly, the semiconductor stack structure 700 may be electrically connected to the interposer 200.

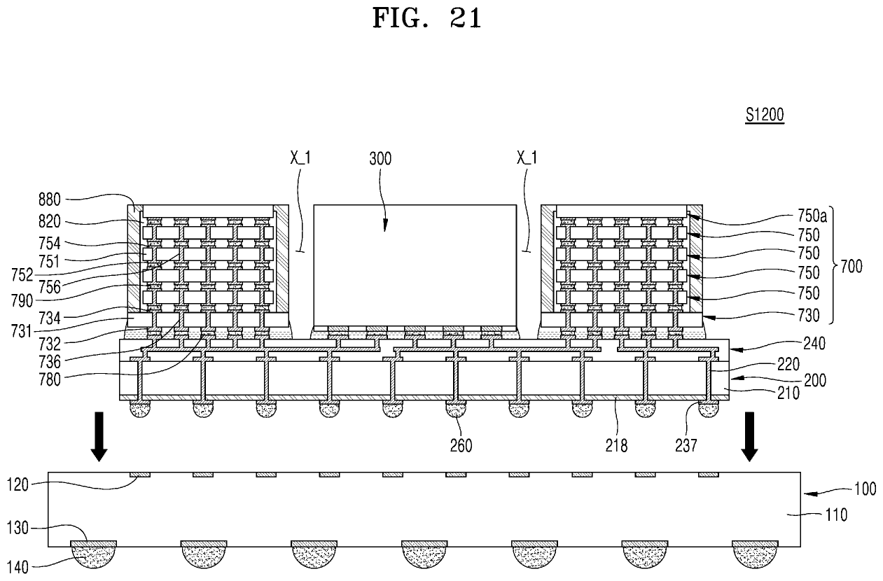

Referring to FIGS. 18 and 21 together, the method S100 of manufacturing the semiconductor package 50 according to an example embodiment of the present disclosure may include mounting the interposer 200 on the package substrate 100 (operation S1200).

Prior to performing operation S1200, the carrier substrate 2100 attached to the lower portion of the interposer 200 may be removed. For example, the carrier substrate 2100 may be removed by laser ablation or heating.

In operation S1200, the interposer connection terminal 260 attached to the interposer lower pad 237 of the interposer 200 may be in contact with the upper package substrate pad 120 of the package substrate 100. Accordingly, in operation S1200, the interposer 200 may be electrically connected to the package substrate 100, and the first semiconductor chip 300 and the semiconductor stack structure 700 mounted on the interposer 200 may also be electrically connected to the package substrate 100.

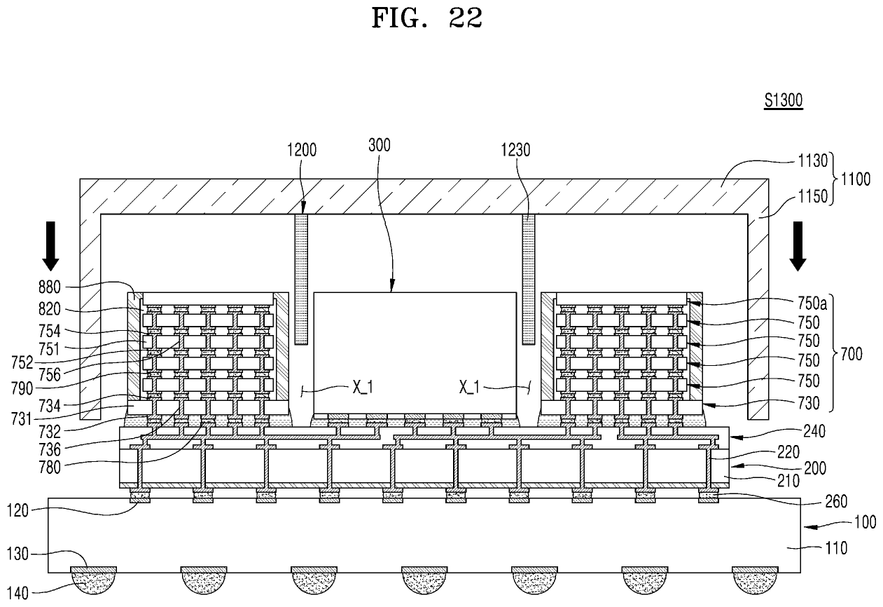

Referring to FIGS. 18 and 22 together, the method S100 of manufacturing the semiconductor package 50 according to an example embodiment of the present disclosure may include mounting the heat radiation member 1100 including the heat blocking member 1200 on the package substrate 100 (operation S1300).

In an example embodiment, in operation S1300, the heat radiation member 1100 may be in contact with an upper surface of the first semiconductor chip 300 and an upper surface of the semiconductor stack structure 700. Also, in operation S1300, the heat blocking member 1200 extending from an inner surface of the heat radiation member 1100 may be arranged in the first space X_1 between the first semiconductor chip 300 and the second semiconductor chip 400 or the second space X_2 between the plurality of the second semiconductor chip 400.

In an example embodiment, after performing operation S1300, a lower surface of the heat blocking member 1200 may be at a higher level than an upper surface of the redistribution structure 240 of the interposer 200. The lower surface of the heat blocking member 1200 may be at a higher level than the upper surface of the redistribution structure 240, and thus, physical damage to the interposer 200 may be prevented by the heat blocking member 1200.

Example embodiments, however, are not limited thereto, and after performing operation S1300, the heat blocking member 1200 may be in contact with the redistribution structure 240 of the interposer 200. In other words, the lower surface of the heat blocking member 1200 may be coplanar with the upper surface of the redistribution structure 240.

Also, when a vertical length of the heat blocking member 1200 is substantially equal to a vertical distance between the upper surface of the first semiconductor chip 300 and the upper surface of the redistribution structure 240, the lower surface of the heat blocking member 1200 may function as a stopper in operation S1300. Accordingly, physical damage to the redistribution structure 240 by the heat blocking member 1200 may be prevented. That is, structural reliability of the semiconductor package 50 may be improved.

The method S100 of manufacturing the semiconductor package 50 according to an example embodiment of the present disclosure may include arranging the heat blocking member 1200 in the first space X_1 between the first semiconductor chip 300 and the semiconductor stack structure 700 and the second space X_2 between the plurality of the semiconductor stack structure 700. Accordingly, thermal interference between the first semiconductor chip 300 and the semiconductor stack structure 700 and thermal interference between the plurality of the semiconductor stack structure 700 may be blocked by the heat blocking member 600, and operational performance of the first semiconductor chip 300 and the semiconductor stack structure 700 may be improved.

Also, the method S100 of manufacturing the semiconductor package 50 according to an example embodiment of the present disclosure may include arranging the heat radiation member 1100 to surround at least a portion of a side surface of the first semiconductor chip 300 and a side surface of the semiconductor stack structure 700. Accordingly, heat generated from the first semiconductor chip 300 and the semiconductor stack structure 700 may be rapidly released to the outside of the semiconductor package 50 through the heat radiation member 1100.

While non-limiting example embodiments have been particularly shown and described, it will be understood that various changes in form and details may be made to embodiments without departing from the spirit and scope of the present disclosure.

1. A semiconductor package comprising:
a package substrate;
an interposer mounted on the package substrate;
a first semiconductor chip mounted on the interposer;
a plurality of second semiconductor chips mounted on the interposer to surround at least a portion of the first semiconductor chip;
a heat radiation member arranged on the first semiconductor chip and the plurality of second semiconductor chips; and
a heat blocking member extending from a portion of the heat radiation member and arranged in at least one space among a first space between the first semiconductor chip and at least one of the plurality of second semiconductor chips and a second space between at least two of the plurality of second semiconductor chips.

2. The semiconductor package of claim 1, wherein a material of the heat blocking member has a thermal conductivity that is lower than a thermal conductivity of a material of the heat radiation member.

3. The semiconductor package of claim 1, wherein a material of the heat blocking member is identical to a material of the heat radiation member, and
the heat blocking member is integrated with the heat radiation member.

4. The semiconductor package of claim 1, wherein the heat blocking member comprises a heat blocking wall extending from a portion of the heat radiation member in a vertical direction and arranged in the first space between the first semiconductor chip and the at least one of the plurality of second semiconductor chips.

5. The semiconductor package of claim 1, wherein the heat blocking member comprises a heat blocking wall extending from a portion of the heat radiation member in a vertical direction and arranged in the second space between the at least two of the plurality of second semiconductor chips.

6. The semiconductor package of claim 5, wherein a surface toward the first semiconductor chip among surfaces of the heat blocking wall is coplanar with a surface toward the first semiconductor chip among surfaces of the plurality of second semiconductor chips.

7. The semiconductor package of claim 1, wherein the heat blocking member comprises:
a first heat blocking wall extending from a first portion of the heat radiation member in a vertical direction and arranged in the first space between the first semiconductor chip and the at least one of the plurality of second semiconductor chips; and
a second heat blocking wall extending from a second portion of the heat radiation member in a vertical direction and arranged in the second space between the at least two of the plurality of second semiconductor chips.

8. The semiconductor package of claim 1, wherein the heat blocking member comprises:
a first heat blocking wall extending from a portion of the heat radiation member in a vertical direction and arranged in the first space between the first semiconductor chip and at least one of the plurality of second semiconductor chips;
a second heat blocking wall extending from the first heat blocking wall and arranged in the second space between the at least two of the plurality of second semiconductor chips; and
a third heat blocking wall arranged outside the plurality of second semiconductor chips, surrounding the first semiconductor chip and the plurality of second semiconductor chips, and connecting the first heat blocking wall to the second heat blocking wall.

9. The semiconductor package of claim 1, wherein, when the semiconductor package is seen in a planar view, the heat blocking member has a quadrangular shape that surrounds a side portion of the first semiconductor chip.

10. The semiconductor package of claim 1, wherein the heat blocking member comprises:
a plurality of first protrusions protruding in a direction toward the first semiconductor chip; and
a plurality of second protrusions protruding in a direction toward at least one of the plurality of second semiconductor chips.

11. The semiconductor package of claim 1, wherein a lower surface of the heat blocking member is spaced apart from an upper surface of the interposer in a vertical direction.

12. The semiconductor package of claim 1, wherein a lower surface of the heat blocking member is in contact with an upper surface of the interposer.

13. The semiconductor package of claim 1, wherein a thickness of the heat blocking member is 50 micrometers to 500 micrometers.

14. A semiconductor package comprising:
a package substrate;
an interposer mounted on the package substrate;
a first semiconductor chip mounted on the interposer;
a plurality of semiconductor stack structures mounted on the interposer to surround at least a portion of the first semiconductor chip, and comprising a plurality of semiconductor chips stacked in a vertical direction;
a heat radiation member arranged on the first semiconductor chip and the plurality of semiconductor stack structures, the heat radiation member comprising:
a first heat radiation wall extending on the first semiconductor chip and the plurality of semiconductor stack structures in a horizontal direction; and
at least one second heat radiation wall extending from a portion of the first heat radiation wall in the vertical direction and surrounding the first semiconductor chip and the plurality of semiconductor stack structures; and
a heat blocking member extending from a portion of the heat radiation member and arranged in at least one space among a first space between the first semiconductor chip and at least one of the plurality of semiconductor stack structures and a second space between at least two of the plurality of semiconductor stack structures.

15.-17. (canceled)

18. The semiconductor package of claim 14, wherein
the at least one second heat radiation wall is a plurality of second heat radiation walls that extend from respective portions of the first heat radiation wall in the vertical direction, and
the heat blocking member comprises:
a first heat blocking wall extending between at least of the plurality of second heat radiation walls, that face each other, and arranged in the first space between the first semiconductor chip and the at least two of the plurality of semiconductor stack structures; and
a second heat blocking wall extending from a portion of one of the plurality of second heat radiation walls and arranged in the second space between the at least two of the plurality of semiconductor stack structures.

19. The semiconductor package of claim 18, wherein a thickness of the first heat blocking wall is greater than a thickness of the second heat blocking wall.

20.-21. (canceled)

22. The semiconductor package of claim 14, wherein a material of the heat blocking member has a thermal conductivity that is lower than a thermal conductivity of a material of the heat radiation member.

23. The semiconductor package of claim 22, wherein the material of the heat radiation member comprises copper, and
the material of the heat blocking member comprises stainless steel.

24. (canceled)

25. The semiconductor package of claim 14, wherein the interposer comprises:
an interposer substrate mounted on the package substrate;
an interposer through electrode passing through at least a portion of the interposer substrate in the vertical direction;
an interposer connection terminal connected to the interposer through electrode and arranged between the interposer substrate and the package substrate; and
a redistribution structure arranged on the interposer substrate and comprising: a redistribution insulating layer; and a redistribution pattern extending within the redistribution insulating layer and connected to the interposer through electrode.

26. A semiconductor package comprising:
a package substrate;
an interposer mounted on the package substrate and comprising:
an interposer substrate;
an interposer through electrode passing through at least a portion of the interposer substrate in a vertical direction;
an interposer connection terminal connected to the interposer through electrode and arranged between the interposer substrate and the package substrate; and
a redistribution structure arranged on the interposer substrate;
a logic semiconductor chip arranged on the redistribution structure of the interposer;
a plurality of semiconductor stack structures arranged on the redistribution structure of the interposer to surround at least a portion of the logic semiconductor chip, and comprising a plurality of memory semiconductor chips stacked in the vertical direction;
a heat radiation member arranged on the logic semiconductor chip and the plurality of semiconductor stack structures; and
a heat blocking member extending from at least a portion of the heat radiation member and arranged in at least one space among a first space between the logic semiconductor chip and at least one of the plurality of semiconductor stack structures and a second space between at least two of the plurality of semiconductor stack structures.

27.-30. (canceled)
